(19) United States
(12) Patent Application Publication
(10) Pub. No.: US 2013/0015996 A1
(43) Pub. Date: Jan. 17, 2013

(54) AD CONVERTER AND INFORMATION PROCESSING APPARATUS

(71) Applicant: Masanori FURUTA, Odawara-shi (JP)

(72) Inventor: Masanori FURUTA, Odawara-shi (JP)

(21) Appl. No.: 13/418,830

(22) Filed: Mar. 13, 2012

(30) Foreign Application Priority Data
Jul. 12, 2011 (JP) P2011-154080

(51) Int. Cl. H03M 1/12

(52) U.S. Cl. 341/172

(57) ABSTRACT

An analog-to-digital converter includes: weighted capacitors connected to each other at one ends thereof, having a capacitance value weighted at a predetermined ratio, and including a variable capacitance capacitor capable of reducing the capacitance value; a comparator including an input to which the one ends of the weighted capacitors are coupled; switches that connect the other ends different from the one ends to any of an input terminal into which an input signal is input, a reference voltage source used for successive approximation of the input signal, a ground, and an open terminal; a successive approximation controller that controls the switches to sample the input signal onto the weighted capacitors, and use the reference voltage source to generate a comparative voltage for the successive approximation, to thereby execute a successive approximation; and a capacitance controller that controls the switches to reduce a capacitance value of the variable capacitance capacitor.

### CROSS-REFERENCE TO RELATED APPLICATION

This application is based upon and claims the benefit of priority from Japanese Patent Application No. 2011-154080, filed on Jul. 12, 2011; the entire contents of which are incorporated herein by reference.

### FIELD

Embodiments described herein relate generally to an analog-to-digital (AD) converter and an information processing apparatus.

In circuit design for a successive approximation register analog-to-digital converter (SAR-ADC), how to cope with excessive input signals is a problem. In the SAR-ADC using a capacitance, a voltage equal to the voltage of an input signal is generated at an input end of a comparator. If an input signal having a voltage higher than a power supply voltage of the comparator is input, a gate of an input transistor of this comparator is broken. As a countermeasure against this, using a high-voltage device as the input transistor of the comparator or adding a voltage-dividing capacitor having a high capacitance between an input node of the comparator and a ground can be considered.

However, using the high-voltage device leads to a reduction in speed and an increase in area. Further, in the case of using the voltage-dividing capacitor, there is a fear that noise is relatively increased with a reduction in input voltage of the comparator. In particular, an increase in noise (deterioration of signal-to-noise ratio) in the case of using the voltage-dividing capacitor influences AD conversion accuracy.

### BRIEF DESCRIPTION OF THE DRAWINGS

FIG. 1 is a circuit diagram showing a configuration of an analog-to-digital (AD) converter according to a first embodiment.

FIG. 2 is a diagram showing an operation state of the AD converter shown in FIG. 1.

FIG. 3 is a circuit diagram showing a specific example of the AD converter according to the first embodiment.

FIG. 4 is a diagram showing an operation state of the AD converter shown in FIG. 3.

FIG. 5A is a diagram showing an operation state of the AD converter according to the first embodiment.

FIG. 5B is a diagram showing an operation state of the AD converter according to the first embodiment.

FIG. 5C is a diagram showing an operation state of the AD converter according to the first embodiment.

FIG. 5D is a diagram showing an operation state of the AD converter according to the first embodiment.

FIG. 6 is a flow chart showing an operation of the AD converter according to the first embodiment.

FIG. 7 is a circuit diagram showing a configuration of an AD converter as a comparative example.

FIG. 8 is a diagram showing an operation example of the AD converter shown in FIG. 7.

FIG. 9 is a circuit diagram showing a configuration of the AD converter according to the second embodiment.

FIG. 10 is a circuit diagram showing a specific example of the AD converter shown in FIG. 9.

FIG. 11 is a diagram showing an operation state of the AD converter shown in FIG. 10.

FIG. 12A is a diagram showing an operation state of the AD converter according to the second embodiment.

FIG. 12B is a diagram showing an operation state of the AD converter according to the second embodiment.

FIG. 12C is a diagram showing an operation state of the AD converter according to the second embodiment.

FIG. 12D is a diagram showing an operation state of the AD converter according to the second embodiment.

FIG. 13 is a flow chart showing an operation of the AD converter according to the second embodiment.

FIG. 14 is a circuit diagram showing a configuration of the AD converter according to the third embodiment.

FIG. 15 is a diagram for illustrating an operation of the AD converter according to the fourth embodiment.

FIG. 16 is a circuit diagram showing a configuration of the AD converter according to the fourth embodiment.

FIG. 17 is a diagram showing an operation state of the AD converter shown in FIG. 16.

FIG. 18 is a circuit diagram showing a specific example of the AD converter shown in FIG. 16.

FIG. 19 is a diagram showing an operation state of the AD converter shown in FIG. 18.

FIG. 20A is a diagram showing an operation state of the AD converter according to the fourth embodiment.

FIG. 20B is a diagram showing an operation state of the AD converter according to the fourth embodiment.

FIG. 20C is a diagram showing an operation state of the AD converter according to the fourth embodiment.

FIG. 20D is a diagram showing an operation state of the AD converter according to the fourth embodiment.

### DETAILED DESCRIPTION

As mentioned above, in the conventional AD converter and information processing apparatus, there is a problem that in the case of handling an excessive input, a reduction in speed and an increase in area as well as an increase in noise are caused. It is an object of embodiments to provide an AD converter and an information processing apparatus that are capable of suppressing a reduction in operating speed and an increase in area required for a circuit and preventing an increase in noise.

To achieve the above-mentioned object, according to an embodiment, an analog-to-digital (AD) converter includes a plurality of weighted capacitors that are connected to each other at one ends thereof, each have a capacitance value weighted at a predetermined ratio, and each include at least one variable capacitance capacitor capable of reducing the capacitance value. This AD converter includes a comparator including an input to which the one ends of the plurality of weighted capacitors are coupled and a plurality of switches configured to connect the other ends different from the one ends of the plurality of weighted capacitors to any one of an input terminal into which an input signal is input, a reference voltage source used for successive approximation of the input signal, a ground, and an open terminal, the one ends being connected to each other. This AD converter further includes a successive approximation controller configured to control the plurality of switches to sample the input signal in the plurality of weighted capacitors, and use the reference voltage source to generate a comparative voltage for successive approximation of the input signal, to thereby execute a successive approximation and a capacitance controller configured to control the plurality of switches to reduce a capacitance value of the variable capacitance capacitor.

### Outline of Embodiment

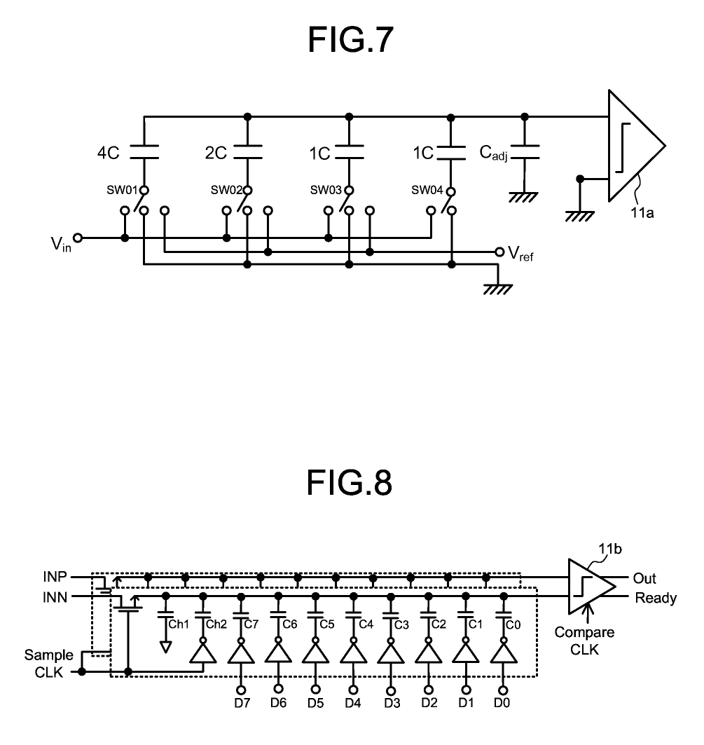

An operation principle of an AD converter according to an embodiment will be described. FIG. 7 is an equivalent circuit diagram of a generally used successive approximation register analog-to-digital (SAR-AD) converter as a comparative example.

As shown in FIG. 7, the typical SAR-AD converter includes a plurality of capacitors weighted by a power of 2 and connected to each other at one ends thereof, a comparator 11a including an input end to which the one ends of the plurality of capacitors are connected, a plurality of switches connected to the other ends of the plurality of capacitors, an adjusting capacitor (C_{adj}) that is connected between the input end of the comparator 11a and a ground, a control circuit (not shown), and the like. In the example shown in FIG. 7, the plurality of capacitors are set to have a capacitance ratio of 4:2:1:1. The plurality of switches are configured to connect the other ends of the plurality of capacitors to any of an input terminal Vᵢₙ, a reference voltage source V_{ref}, and a ground.

The plurality of weighted capacitors shown in FIG. 7 are, at the one ends thereof, connected to the reference voltage source V_{ref} or the ground, to function as capacitance DA converters (capacitance DACs). Specifically, an output of the comparator 11a is used to generate a comparative voltage (voltage applied on the capacitor) that is necessary for AD conversion of the next bit, so that the AD conversion of the next bit is realized.

FIG. 8 shows a circuit example of an 8-bit AD converter to which the SAR-AD converter shown in FIG. 7 is applied. In the example shown in FIG. 8, a differential signal is used as the input signal and the SAR-AD converter shown in FIG. 7 is connected to each of a positive electrode side and a negative electrode side of the input terminal. The result of each of the positive electrode side and the negative electrode side of the input signal being subjected to AD conversion appears in the output terminal of the comparator 11b. When conversion of the most significant bit (MSB) is completed, the result of comparison of the MSB (D7 in the figure) that is performed by the comparator 11b is used to control one (C7) of the capacitors of the capacitance DACs and compare the next bit. After that, when conversion of all bits from D7 to D0 is completed in the same manner, the obtained bits are arranged and output as a digital signal by an arithmetic unit (not shown).

Here, a voltage Vₒᵤₜ (internal amplitude of the SAR-AD converter) to be input into the input terminal of the comparator 11a of the SAR-AD converter shown in FIG. 7 is expressed by Equation 1.

$${V}_{out} = ( - \frac{8}{8 + ( {C}_{adj} / C )} {V}_{i n} + \frac{4}{8 + ( {C}_{adj} / C )} {V}_{ref} D [ 2 ] + \frac{2}{8 + ( {C}_{adj} / C )} {V}_{ref} D [ 1 ] + \frac{1}{8 + ( {C}_{adj} / C )} {V}_{ref} D [ 0 ] ) \qquad ( 1 )$$

Where, Vᵢₙ represents a voltage to be input into the input terminal, D[i] (i=1, 2, 3) represents an AD conversion result (“1” or “0”) in each conversion cycle, and V_{ref} represents a reference voltage (input range of the AD converter).

By simplifying Equation 1, the following expression is obtained.

$${V}_{out} = \frac{1}{1 + {C}_{adj} / 8 C} ( - {V}_{i n} + \frac{1}{2} {V}_{ref} D [ 2 ] + \frac{1}{4} {V}_{ref} D [ 1 ] + \frac{1}{8} {V}_{ref} D [ 0 ] ) \qquad ( 2 )$$

Equation 2 shows that the adjusting capacitor C_{adj} has no influence on the conversion operation of the AD converter. Further, it can be seen that by increasing the capacitance value of the adjusting capacitor C_{adj}, the internal amplitude of the SAR-AD converter can be reduced. In accordance with this principle, by adding the adjusting capacitor C_{adj} that is sufficiently larger than (or almost as large as) the capacitance of a main-body of the capacitance DACs (total capacitance of the weighted capacitors) to the input end of the comparator 11a, amplitude adjustment that prevents an excessive input into the comparator can be performed.

However, the amplitude adjustment by the adjusting capacitor C_{adj} directly influences an area required for a circuit of the SAR-AD converter. That is, if the capacitance value of the adjusting capacitor is increased overestimating the excessive input, the area required for the circuit is also increased in proportion to this. The same applies to the case where the differential signal is used as the input signal as shown in FIG. 8.

In the AD converter according to the embodiment, by realizing amplitude adjustment without depending on the adjusting capacitor, it is possible to suppress a reduction in operating speed and an increase in required area and prevent an increase in noise. Specifically, by providing the capacitance DACs of the SAR-AD converter with variable capacitance capacitors, an input voltage to be input into the comparator can be reduced.

### Configuration of First Embodiment

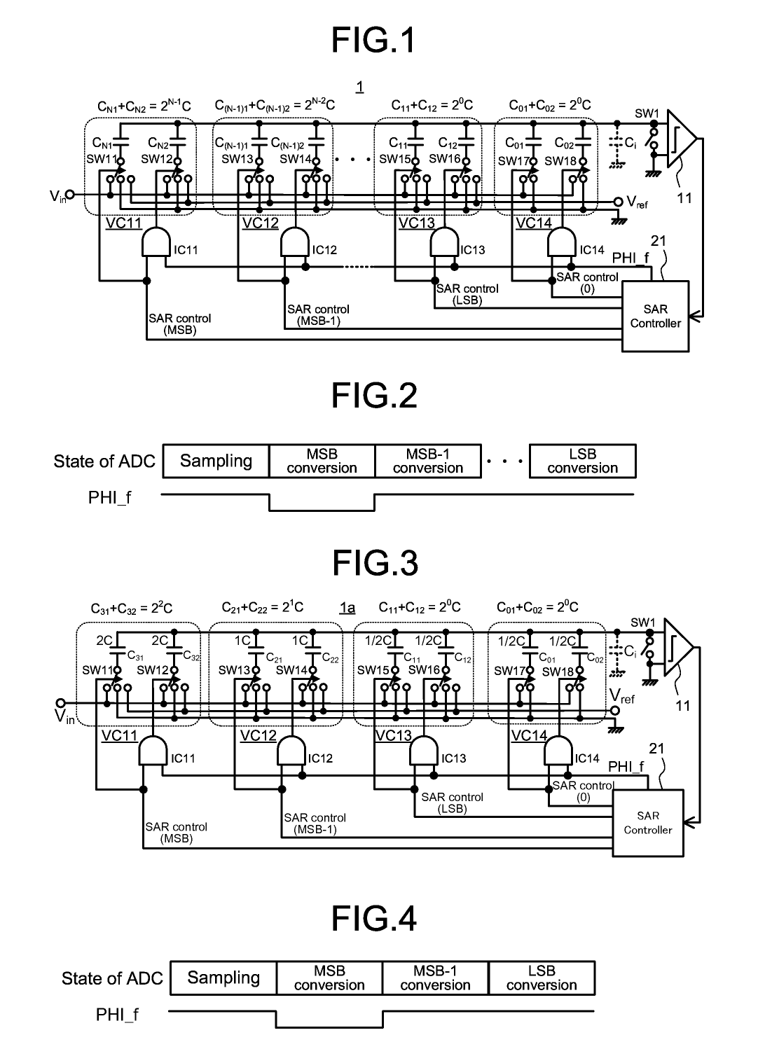

Hereinafter, referring to FIGS. 1 to 6, an AD converter according to a first embodiment will be described in detail. As shown in FIG. 1, the AD converter 1 according to this embodiment includes a plurality of variable capacitor sections VC11 to VC13 each having a capacitance value weighted by a power of 2, a variable capacitor section VC14 having the same capacitance value as the variable capacitor section VC13 having the smallest capacitance value among the variable capacitor sections VC11 to VC13, a comparator 11, AND gate sections IC11 to IC14, and a controller 21. The variable capacitor sections VC11 to VC14 constitute capacitance DACs of the AD converter 1. Assuming that a unit capacitance value is represented by C, the total capacitance of each of the variable capacitor sections VC11 to VC14 is 2ⁿC (where n=1, 2, 3, . . . ).

The variable capacitor section VC11 includes capacitors C_{N1} and C_{N2} and switches SW11 and SW12. The capacitors C_{N1} and C_{N2} are capacitors that have the same capacitance value and are connected to each other at one terminals (common terminals) thereof. To the other terminals of the capacitors C_{N1} and C_{N2}, connected are common terminals of the switches SW11 and SW12. The switches SW11 and SW12 function to connect, under control by an external device, the other terminals of the capacitors C_{N1} and C_{N2} to any one of the input terminal Vᵢₙ, the reference voltage source V_{ref}, the ground, and an open end, the other terminals being connected to the common terminals of the switches SW11 and SW12.

The variable capacitor sections VC12 to VC14 also have the same configuration as the variable capacitor section VC11. Specifically, the variable capacitor sections VC12 to VC14 respectively include capacitors C_{(N-1)1} and C_{(N-1)2} to capacitors C₀₁ and C₀₂ and switches SW13 and SW14 to switches SW17 and SW18. It should be noted that the switches SW17 and SW18 of the variable capacitor section VC14 do not need to connect the other terminals of the capacitors C₀₁ and C₀₂ to the reference voltage source V_{ref}, the other terminals being connected to the common terminals of the switches SW17 and SW18.

Regarding the variable capacitor sections VC11 to VC13, the sum of capacitance values of the paired capacitors C_{N1} and C_{N2} to the sum of the paired capacitors C₁₁ and C₁₂ are set to be values weighted by a power of 2 (assuming that a capacitance value of a unit capacitor is represented by C, 2^{N-1}C to 2⁰C). The sum of capacitance values of the paired capacitors C₀₁ and C₀₂ in the variable capacitor section VC14 is the same (2⁰C) as in the variable capacitor section VC13.

The comparator 11 determines whether a potential difference between the input terminals is equal to or larger than a predetermined value, or smaller than the predetermined value and outputs a comparative output. For example, if the potential difference between the input terminals is equal to or larger than the predetermined potential difference, the comparator 11 outputs “1”, and if it is smaller than the predetermined potential difference, the comparator 11 outputs “0”. In the example shown in FIG. 1, to one input terminal of the comparator 11, connected are the common terminals of the capacitors C_{(N-1)1} and C_{(N-1)2} to the capacitors C₀₁ and C₀₂ in the variable capacitor sections VC11 to VC14, and to the other input terminal, connected is the ground. It should be noted that between the input terminals of the comparator 11, connected is a switch SW1 that shunts between those terminals.

The controller 21 is an arithmetic unit that executes operations for a successive approximation. The controller 21 sends, according to an output of the comparator 11, control signals to successive approximation control lines (SAR_control) connected to the variable capacitor sections VC11 to VC14 and to a capacitance control line (PHI_f) that controls the total capacitance of each of the variable capacitor sections VC11 to VC14 (sum of capacitance values of the paired capacitors).

The successive approximation control lines are connected to the switches SW11 to SW18. Thus, via the control signals sent to the successive approximation control lines, the controller 21 controls the common terminals of the switches SW11 to SW18 to be connected to any of the input terminal Vᵢₙ the reference voltage source V_{ref}, and the ground.

The AND gate sections IC11 to IC14 function to turn on/off connection of the one capacitors of the paired capacitors included in the variable capacitor sections VC11 to VC14. As shown in FIG. 1, to one input terminals of the AND gate sections IC11 to IC14, connected are the successive approximation control lines, and to the other input terminals, connected is the capacitance control line. Output terminals of the AND gate sections IC11 to IC14 are respectively connected to the switches SW12 and SW14 to SW18 connected to the one capacitors (C_{N2} and C_{(N-1)2} to C₀₂) of the variable capacitor sections VC11 to VC14 so as to act to connect and disconnect the common terminals and open terminals of the switches SW12 to SW18. Thus, via the control signal sent to the capacitance control line, the controller 21 is capable of controlling the total capacitance of each of the variable capacitor sections VC11 to VC14 to be reduced by half.

FIG. 2 shows a relationship between the operation of the AD converter 1 and the control signal sent to the capacitance control line. As shown in FIG. 2, while the AD converter 1 is converting the most significant bit (MSB: most upper bit), the controller 21 sets the control signal sent to the capacitance control line (PHI-f) to “0”. Specifically, during a period when the control signal sent to the capacitance control line is “0”, the AND gate sections IC11 to IC14 output “0”, and thus out of the group of the paired capacitors in the variable capacitor sections VC11 to VC14, the capacitors C_{N2} to C₀₂ are disconnected and only the capacitors C_{N1} to C₀₁ are connected. This means that during MSB conversion, the total capacitance of the variable capacitor sections VC11 to VC14 is reduced by half. It should be noted that the ratio of the total capacitance between the variable capacitor sections VC11 to VC13 is not changed before and after the total capacitance is reduced by half.

### Specific Example and Operation of First Embodiment

Next, referring to FIG. 3, a specific example and an operation of an AD converter 1 according to the first embodiment will be described. FIG. 3 shows an AD converter 1a that converts an input signal into a 3-bit signal, the AD converter 1a being obtained by setting a resolution N to 3 in the AD converter 1 shown in FIG. 1.

As shown in FIG. 3, the AD converter 1a according to this example includes variable capacitor sections VC11 to VC14. Assuming that a unit capacitance is represented by C, the variable capacitor sections VC11 to VC14 each have a capacitance so that the ratio of 4C (=2C+2C), 2C (=1C+1C), 1C (=1C/2+1C/2), and 1C can be satisfied. It should be noted that the AD converter 1a shown in FIG. 3 includes no adjusting capacitor C_{adj} for handling excessive input signals.

A capacitor Cᵢ between an input end of the comparator 11 and a ground is a parasitic capacitance that parasitizes the input of the comparator and a wire itself.

In the AD converter 1 (AD converter 1a) according to the first embodiment, the total capacitance of the capacitance DACs is reduced in at least one cycle of an AD conversion cycle starting from an MSB conversion cycle. That is, by reducing the total capacitance of the capacitance DACs and thus relatively reducing the ratio between the parasitic capacitance Cᵢ and the total capacitance, the amplitude (internal amplitude) of a voltage to be input into the input terminal of the comparator 11 is attenuated. Specifically, by substituting C in Equation 1 by C′ where C>C′, without influencing the SAR-AD conversion operation, even the excessive input into the comparator 11 can be prevented (Equation 3).

$${V}_{out} = \frac{1}{1 + {C}_{i} / ( 8 {C}^{′} )} ( - {V}_{i n} + \frac{1}{2} {V}_{ref} D [ 2 ] + \frac{1}{4} {V}_{ref} D [ 1 ] + \frac{1}{8} {V}_{ref} D [ 0 ] ) \qquad ( 3 )$$

At this time, if the ratio between the capacitance value from the MSB to the least significant bit (LSB) (capacitance value of the variable capacitor sections VC11 to VC13) and the smallest capacitance (capacitance value of the variable capacitor section VC14) is set to be a power of 2, without influencing the SAR-AD conversion, the excessive input can be prevented.

Reduction of the total capacitance of the capacitance DACs, that is, substitution of C by C′ can be realized by controlling the switches SW12, SW14, SW16 and SW18 by the AND gate sections IC11 to IC14. Specifically, during a period equal to or longer than an MSB conversion period in an SAR-AD conversion cycle shown in FIG. 4, the controller 21 sends to the capacitance control line a control signal of “0”. In response to this control signal, outputs of the AND gate sections IC11 to IC14 are set to “0”, and thus the switches SW12 and SW14 to SW18 connect their common terminals to the “open terminals” to bring the one ends of capacitors C₃₂, C₂₂ to C₀₂ into floating state. As a result, the total capacitance (8C in FIG. 3) of the variable capacitor sections VC11 to VC14 is reduced by half (4C in FIG. 3).

In the AD converter according to this embodiment, during the MSB conversion period (or period longer than the MSB conversion period) when the amplitude (internal amplitude) to be input into the comparator is increased, the capacitance values of the capacitors of the capacitance DACs are reduced, and thus it is not necessary to use a high-voltage device as an input device for the comparator and it is possible to realize a high-speed operation at low power consumption. Further, by reducing the capacitances of the capacitance DACs, the ratio to the parasitic capacitance Cᵢ can be reduced, and thus it is also not necessary to provide an additional capacitor corresponding to the adjusting capacitor C_{adj}.

It should be noted that although in the example shown in FIG. 3, the AD converter 1a includes no adjusting capacitor C_{adj}, it is not limited thereto. An additional capacitor having a capacitance sufficiently smaller than (or smaller than) the capacitor capacitance of the capacitance DACs may be provided.

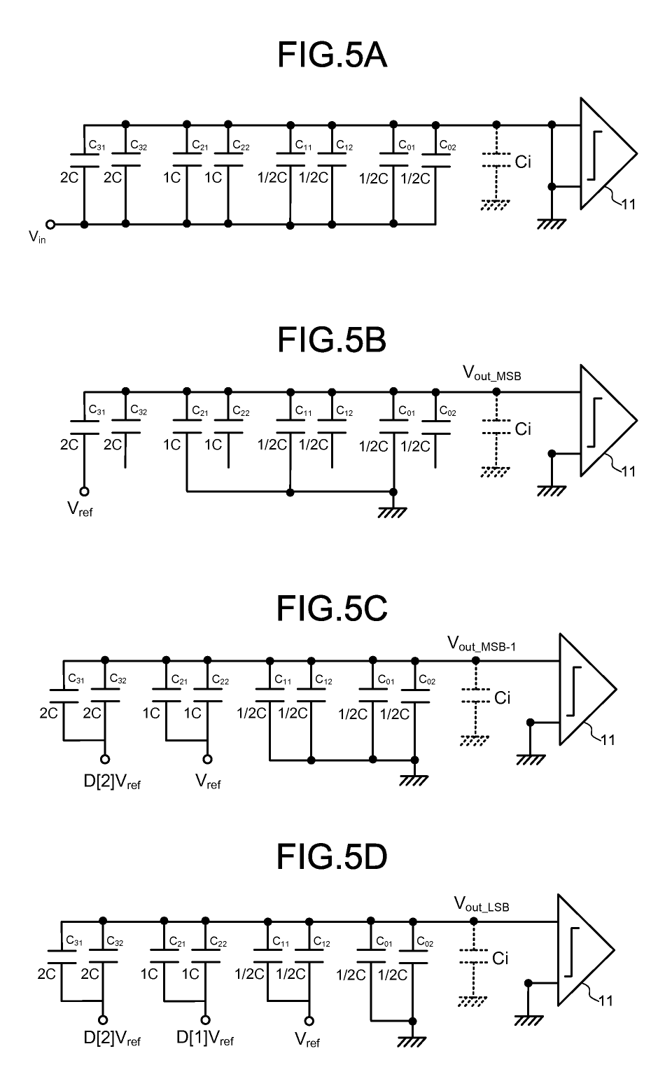

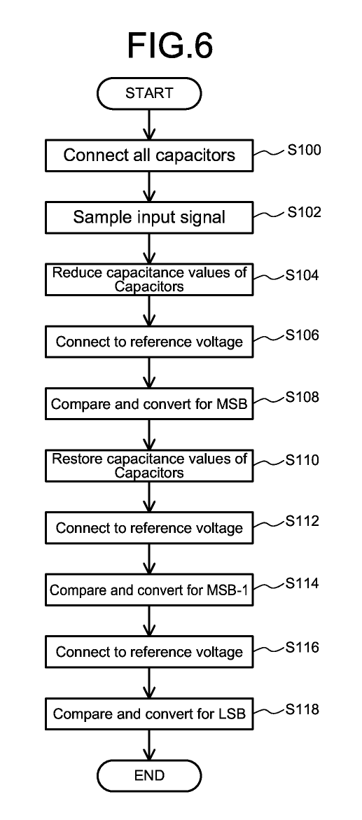

Next, referring to FIGS. 5A to 5D and FIG. 6, the operation of the AD converter according to the first embodiment will be described. FIGS. 5A to 5D show operation states of the AD converter 1a using equivalent circuits. The SAR-AD conversion of the AD converter according to this embodiment includes four phases of sampling (FIG. 5A), MSB conversion (FIG. 5B), MSB-1 conversion (FIG. 5C), and LSB conversion (FIG. 5D) and the amplitude attenuation control is performed only during the MSB conversion period as shown in FIG. 4.

First, the controller 21 sends to the capacitance control line a control signal of “1” and controls the switches SW11 to SW18 via the successive approximation control lines to connect the one ends of the capacitors C₃₁. C₃₂ to C₀₂ to the input terminal Vᵢₙ. Further, the controller 21 turns on the switch SW1 connected between the input terminals of the comparator 11. As a result, as shown in FIG. 5A, common terminals of the capacitors C₃₁, C₃₂ to C₀₂ are connected to the ground and the other terminals are connected to the input terminal Vᵢₙ (Step 100 (hereinafter “Step” will be abbreviated as “S”, e.g. “S100”)).

When an input signal is input into the input terminal Vᵢₙ at a timing of Step 100, all capacitors sample the input signal (S102).

When the sampling is completed, the controller 21 sends to the capacitance control line a control signal of “0” to control the switches SW12 and SW14 to SW18 to connect the one ends of the capacitors C₃₂, C₂₂ to C₀₂ to open ends. Thus, the capacitance value of the variable capacitor sections VC11 to VC14 is reduced by half, so that the total capacitance of the capacitance DACs of the AD converter 1 is reduced (S104).

When the total capacitance of the capacitance DACs of the AD converter 1a is reduced, the controller 21 sends, as shown in FIG. 5B, to the successive approximation control lines control signals to control the switch SW11 to connect the one end of the capacitor C₃₁ to the reference voltage source V_{ref} and control the switches SW13, 15, and 17 to connect the one ends of the capacitors C₂₁, C₁₁, and C₀₁ to the ground. Further, the controller 21 opens the switch SW1 (S106).

In the operation state shown in FIG. 5B, the controller 21 uses the comparator 11 to compare and convert the MSB (S108). At this time, a voltage Vₒᵤₜ_{_{—}}_{MSB} that appears at the input terminal of the comparator 11 is expressed by Equation 4.

$${V}_{out \_ MSB} ( b ) = \frac{1}{1 + {C}_{i} / ( 4 C )} ( - {V}_{i n} + \frac{1}{2} {V}_{ref} ) \qquad ( 4 )$$

For example, assuming that Cᵢ is 2C, the internal amplitude can be attenuated by about 20% in comparison with a general AD conversion operation by using the floating state.

Next, the controller 21 sends to the capacitance control line a control signal of “1” to control the switches SW12 and SW14 to SW18 to disconnect the one ends of the capacitors C₃₂ and C₂₂ to C₀₂ from the open ends (S110). In this manner, the total capacitance of the capacitance DACs is restored.

When the total capacitance of the capacitance DACs is restored, the controller 21 controls, as shown in FIG. 5C, the switches SW11 and SW12 to connect the one ends of the capacitors C₃₁ and C₃₂ to either the reference voltage source V_{ref} or the ground and controls the switches SW13 and SW14 to connect the one ends of the capacitors C₂₁ and C₂₂ to the reference voltage source and the switches SW15 to SW18 to connect the one ends of the capacitors C₁₁ and C₁₂ to C₀₂ to the ground (S112). Here, in the figure, “D[2]V_{ref}” represents a product of the output (“1” or “0”) of the comparator 11 and the reference voltage source V_{ref}, which is obtained during the MSB conversion period. Thus, in the MSB conversion cycle, when the comparator 11 outputs “1”, the one ends of the capacitors C₃₁ and C₃₂ are connected to the reference voltage source V_{ref}. Meanwhile, when the comparator 11 outputs “0”, the one ends of the capacitors C₃₁ and C₃₂ are connected to the ground.

When the total capacitance of the capacitance DACs is restored and the predetermined capacitors are connected to the reference voltage source, the controller 21 uses the comparator 11 to compare and convert the lower-order bit (MSB-1) of the MSB (S114). At this time, a voltage that appears at the input terminal of the comparator 11 is expressed by Equation 5.

$${V}_{out \_ MSB - 1} ( b ) = \frac{1}{1 + {C}_{i} / ( 8 C )} ( - {V}_{i n} + \frac{1}{2} {V}_{ref} D [ 2 ] + \frac{1}{4} {V}_{ref} ) \qquad ( 5 )$$

That is, an operation similar to a second cycle of the general SAR-AD conversion is realized.

When the conversion of the lower-order bit of the MSB is completed, the controller 21 controls, as shown in FIG. 5D, the switches SW13 and SW14 to connect the one ends of the capacitors C₂₁ and C₂₂ to either the reference voltage source V_{ref} or the ground and controls the switches SW15 and SW16 to connect the one ends of the capacitors C₁₁ and C₁₂ to the reference voltage source V_{ref} (S116). Here, in the figure, “D[1]V_{ref}” represents a product of the output of the comparator 11 and the reference voltage source V_{ref}, which is obtained during an MSB-1 conversion period. Thus, in an MSB-1 conversion cycle, when the comparator 11 outputs “1”, the one ends of the capacitors C₂₁ and C₂₂ are connected to the reference voltage source V_{ref}. Meanwhile, when the comparator 11 outputs “0”, the one ends of the capacitors C₂₁ and C₂₂ are connected to the ground.

When the predetermined capacitors are connected to the reference voltage source, the controller 21 uses the comparator 11 to compare and convert the LSB (S118).

As mentioned above, in the AD converter according to this embodiment, during the MSB conversion period (or period longer than the MSB conversion period), the total capacitance of the capacitance DACs is reduced, and thus it is possible to suppress the influence of the excessive input signal without providing the adjusting capacitor C_{adj}. Further, in the AD converter according to this embodiment, the total capacitance constituting the capacitance DACs is set to 2ⁿC where the unit capacitance value is represented by C, and thus without changing the total capacitance in the general SAR-ADC nor providing the adjusting capacitor C_{adj}, the internal amplitude of the capacitance DACs can be attenuated.

It should be noted that although in the example described above with reference to FIGS. 1 to 5D, the division ratio of the smallest capacitance is set as 1/2, it is not limited thereto. For example, if the division ratio is set to be smaller, such as 1/4, 1/6, etc., it is possible to enhance the amplitude attenuation effect. Further, although in the above-mentioned example, the capacitance value of the capacitors of the capacitance DACs is weighted by a power of 2, the present invention is also not limited thereto. It may also be weighted by a power of a value other than 2.

In addition, although in the above-mentioned example, some capacitors of the capacitance DACs are held in floating state only during the MSB conversion period, any period except for the LSB conversion period may be set as the amplitude attenuation period. Using full capacitance during the LSB conversion period is due to thermal noise of the capacitance DACs. The thermal noise is calculated by kT/C (where k is Boltzmann constant, T is a temperature, and C is the total capacitance of the capacitance DACs) and increases with a reduction in capacitance. During determining the LSB, the comparator processes a signal amplitude excessively smaller than that in the MSB, and thus it is desirable to use the total capacitance.

### Configuration According to Second Embodiment

Next, an AD converter according to a second embodiment will be described in detail. The AD converter according to the second embodiment is obtained by omitting, in the AD converter according to the first embodiment, the capacitance reduction functions of some capacitors (e.g., the variable capacitor section VC13 associated with LSB conversion and the variable capacitor section VC14 having the same capacitance as the variable capacitor section VC13). In the following description, the same elements as in the first embodiment will be denoted by the same reference symbols and the duplicated description will be omitted.

The configuration of reducing the capacitance value of all capacitors constituting the capacitance DACs as in the AD converter according to the first embodiment can be realized relatively easily. On the other hand, if a usable value of the smallest capacitance is limited due to limitation on a design process and the like, in the configuration of reducing the capacitance values of all capacitors, the signal amplitude reduction effect is limited. In view of this, in the AD converter according to the second embodiment, by setting so that out of the capacitors of the capacitance DACs, the capacitors each having a small capacitance are not reduced in capacitance and the other capacitors are divided and reduced in capacitance, the amplitude is attenuated without changing the smallest capacitance.

In the SAR-ADC, assuming that the number of the capacitors to be subjected to AD conversion is represented by m, out of the terminals of the capacitors from m−1 to the LSB, one ends (one ends not being the common ends) that are not connected to an comparator input are all connected to the ground. Then, by setting the ratio of the total capacitance between the capacitors to be subjected to AD conversion and the other capacitors to be a power of 2, without dividing the capacitance of the LSB and the smallest capacitance of the capacitor, the amplitude attenuation can be achieved.

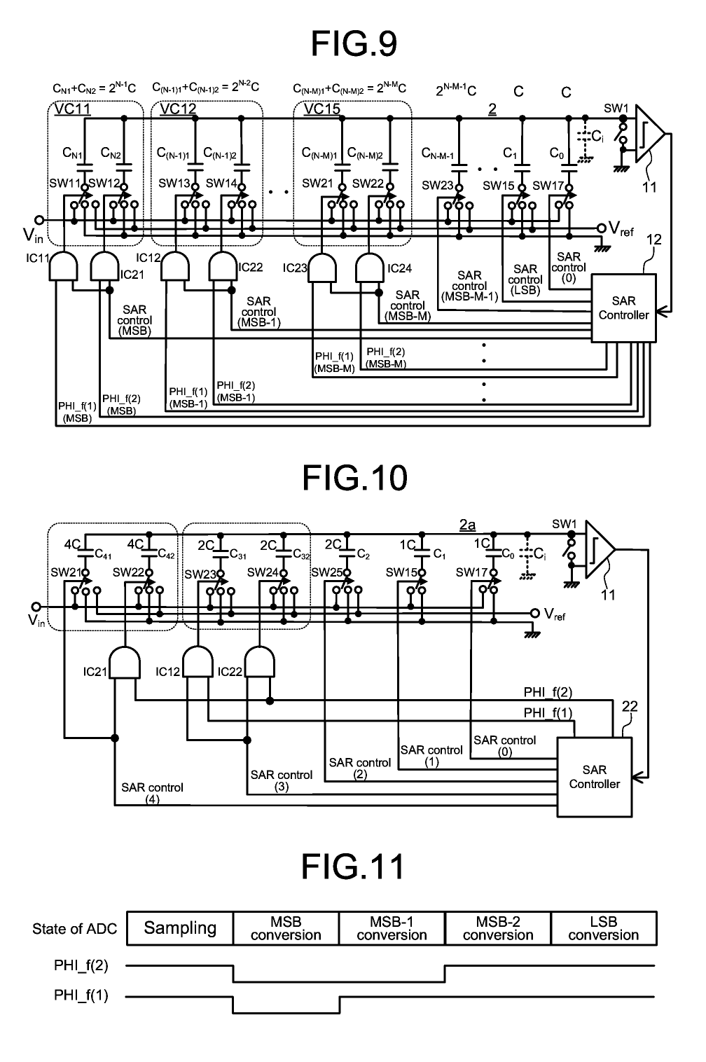

As shown in FIG. 9, in the AD converter 2 according to the second embodiment, regarding a range of from the variable capacitor section VC11 associated with MSB conversion of the capacitance DACs to a variable capacitor section VC15 associated with Mth-bit conversion, there are provided AND gate sections IC11 to IC24 so that the capacitances thereof can be reduced. Further, regarding a range from capacitors C_{N-M-1} to C₁ and the capacitor C₀ having the same capacitance as the capacitor C₁, no AND gate is provided so that the capacitances of the capacitors are fixed, the capacitor C_{N-M-1} being associated with M−1th bit conversion, the capacitor C₁ being associated with LSB conversion out of the capacitance DACs. It should be noted that the capacitance value of each of the variable capacitor sections and the capacitors within a range of from the variable capacitor section VC11 associated with MSB processing to the capacitor C₁ that processes the LSB is weighted by a power of 2, and thus control is performed such that even if the total capacitance of the variable capacitor sections VC11 to VC15 is reduced, the weight ratio applied to the capacitors of the capacitance DACs is maintained.

### Specific Example and Operation of Second Embodiment

Next, referring to FIGS. 10 and 11, a specific example and an operation of the AD converter 2 according to the second embodiment will be described. FIG. 10 shows an AD converter 2a that converts an input signal into a 4-bit signal, the AD converter 2a being obtained by setting the resolution N to 4 in the AD converter 2 shown in FIG. 9.

As shown in FIG. 10, the AD converter 2a according to this example includes two variable capacitor sections that serve to process the MSB and the MSB-1 and three fixed capacitors that serve to process the MSB-2 and the following bits. Assuming that the unit capacitance is represented by C, the two variable capacitor sections and the three fixed capacitors (C₄₁+C₄₂, C₃₁+C₃₂, C₂, C₁, and C₀) each have a capacitance so that the ratio of 8C (=4C+4C), 4C (=2C+2C), 2C, 1C and 1C can be satisfied. It should be noted that also in the AD converter 2a shown in FIG. 10, no adjusting capacitor C_{ad} for handling the excessive input signal is provided. A capacitor Cᵢ between an input end of the comparator 11 and a ground is a parasitic capacitance that parasitizes the input of the comparator and a wire itself.

The AD converter 2a shown in FIG. 10 is a 4-bit SAR-AD converter, in which out of the capacitors constituting the 4-bit capacitance DACs, only the capacitors C₄₁ and C₄₂ and the capacitors C₃₁ and C₃₂ that process the MSB and the MSB-1 are divided. In other words, a configuration in which only the capacitors that process the MSB and the capacitor that process the MSB-1 are reduced in capacitance is adopted.

As shown in FIG. 10, the AD converter 2a includes the capacitors C₄₁ and C₄₂ that serve to process the MSB, the capacitors C₃₁ and C₃₂ that serve to process a second bit, the capacitor C₂ that serves to process a third bit, the capacitor C₁ that serves to process the LSB, the capacitor C₀ having the same capacitance value as the capacitor C₁. One ends of the respective capacitors are connected to one input terminal of the comparator 11 and the other ends are connected to common terminals of switches SW21 to SW25, SW15, and SW17. The switches SW21 and SW25 connect the other ends of the capacitors C₄₁ and C₂ to any of an input terminal Vᵢₙ, a reference voltage source V_{ref}, and a ground. The switches SW22 to SW24 connect the other ends of the capacitors C₄₂ to C₃₂ to any of the input terminal Vᵢₙ, the reference voltage source V_{ref}, the ground, and an open end. The switches SW15 and SW17 connect the other ends of the capacitors capacitor C₁ and C₀ to the input terminal Vᵢₙ or the ground.

Between the input terminals of the comparator 11, connected is a switch SW1 for shunting. Further, the other input terminal of the comparator 11 is connected to the ground. A controller 22 sends, according to an output of the comparator 11, control signals to successive approximation control lines (SAR_control) and two capacitance control lines (PHI_f(2) and PHI_f(1)).

The successive approximation control lines are connected to the switch SW21, one input ends of the AND gate sections IC21, IC12, and IC22, and the switches SW25, SW15 and SW17. Further, out of the capacitance control lines, the line PHI_f(1) is connected to the other input end of the AND gate section IC12 and the line PHI_f(2) is connected to the other input ends of the AND gate sections IC21 and IC22.

FIG. 11 shows a relationship between the operation state of the AD converter and the control signals sent to the capacitance control lines by the controller 22. As shown in FIG. 11, the controller 22 according to this embodiment sends, during an MSB-processing period, to the line PHI_f(1) a control signal of “0”, and during the MSB-processing period and an MSB-1-processing period, to the line PHI_f(2) a control signal of “0”. Thus, the controller 22 controls, during the MSB-processing period, the switches SW22 to SW24 to connect the one ends of the capacitors C₄₂, C₃₁, and C₃₂ to the open ends (brought them into floating state). Further, the controller 22 controls, during the MSB-1-processing period, the switches SW22 and SW24 to connect the one ends of the capacitors C₄₂ and C₃₂ to open ends.

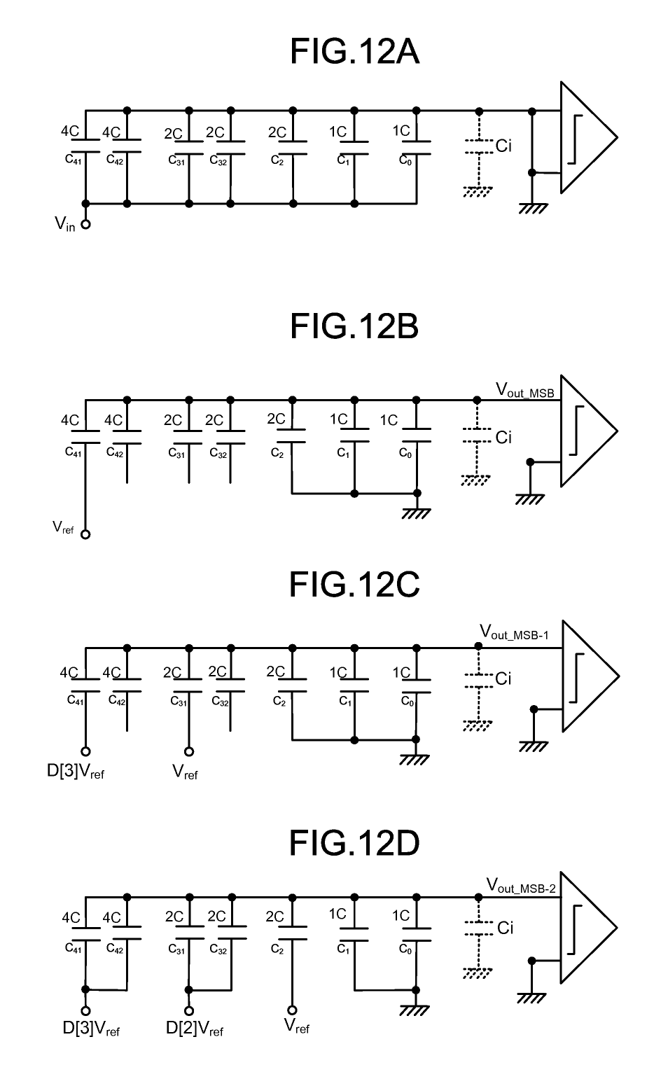

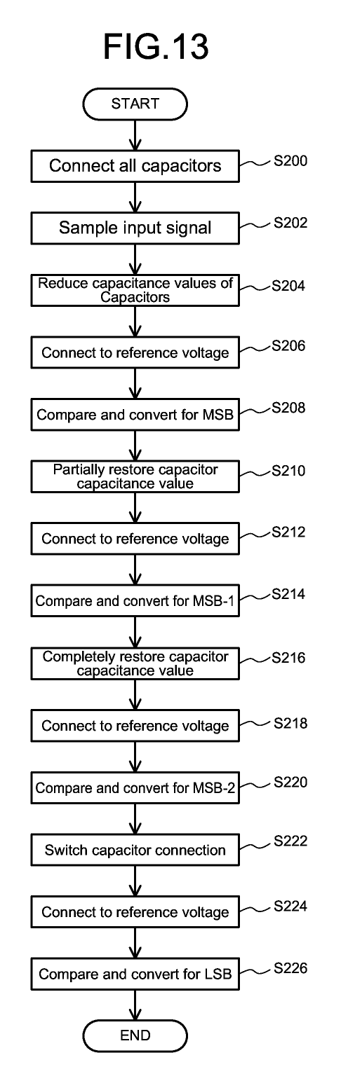

Next, referring to FIGS. 12A to 12D and FIG. 13, the operation of the AD converter according to the second embodiment will be described. FIGS. 12A to 12D show operation states of the AD converter 2a using equivalent circuits. The SAR-AD conversion of the AD converter according to this embodiment includes five phases of sampling (FIG. 12A), MSB conversion (FIG. 12B), MSB-1 conversion (FIG. 12C), MSB-2 conversion (FIG. 12D), and LSB conversion (not shown) and the amplitude attenuation control is performed during the MSB conversion period and the MSB-1 conversion period as shown in FIG. 13.

First, the controller 22 sends to the capacitance control lines control signals of “1” and controls the switches SW21 to SW25, SW15, and SW17 via the successive approximation control lines to connect one ends of the capacitors C₄₁ to C₀ to the input terminal Vᵢₙ. Further, the controller 22 turns on the switch SW1 connected between the input terminals of the comparator 11. As a result, as shown in FIG. 12A, common terminals of the capacitors C₄₁ to C₀ are connected to the ground and the other terminals are connected to the input terminal Vᵢₙ (S200).

When an input signal is input into the input terminal Vᵢₙ at a timing of Step 200, all capacitors sample the input signal (S202).

When the sampling is completed, the controller 22 sends to the two capacitance control lines control signals of “0” to control the switches SW22 to SW24 to connect the one ends of the capacitors C₄₂, C₃₁, and C₃₂ to open ends. Thus, the capacitor capacitance for MSB processing is reduced by half and the capacitors for MSB-1 processing are held in floating state, so that the total capacitance of the capacitance DACs of the AD converter 2a is reduced (S204).

When the total capacitance of the capacitance DACs of the AD converter 2a is reduced, the controller 22 sends to the successive approximation control lines control signals as shown in FIG. 12B to control the switch SW21 to connect the one end of the capacitor C₄₁ to the reference voltage source V_{ref} and control the switches SW25, SW15, and SW17 to connect the one ends of the capacitors C₂, C₁, and C₀ to the ground. Further, the controller 22 opens the switch SW1 (S206).

In the operation state shown in FIG. 12B, the controller 22 uses the comparator 11 to compare and convert the MSB (S208). At this time, a voltage Vₒᵤₜ_{_{—}}_{MSB} that appears at the input terminal of the comparator 11 is expressed by Equation 6.

$${V}_{out \_ MSB} ( b ) = \frac{1}{1 + {C}_{adj} / ( 8 C )} ( - {V}_{i n} + \frac{1}{2} {V}_{ref} ) \qquad ( 6 )$$

It should be noted that an output voltage in the case where the floating state is not used is expressed by Equation 7.

$${V}_{out } ( b ) = \frac{1}{1 + {C}_{adj} / ( 16 C )} ( - {V}_{i n} + \frac{1}{2} {V}_{ref} ) \qquad ( 7 )$$

Thus, it can be seen that by bringing some capacitors of the capacitance DACs into floating state, a reduction of the internal amplitude can be achieved.

Next, the controller 22 sends to the capacitance control line PHI_f(1) a control signal of “1” to control the switch SW23 to disconnect the one end of the capacitor C₃₁ from the open end (S210). In this manner, the total capacitance of the capacitance DACs is partially restored.

When the capacitor C₃₁ is disconnected from the open end, the controller 22 controls, as shown in FIG. 12C, the switch SW11 to connect the one end of the capacitor C₄₁ to either the reference voltage source V_{ref} or the ground and controls the switch SW23 via the AND gate section IC12 to connect the one end of the capacitor C₃₁ to the reference voltage source (S212). Here, in the figure, “D[3]V_{ref}” represents a product of the output (“1” or “0”) of the comparator 11 and the reference voltage source V_{ref}, which is obtained during the MSB conversion period. Thus, the one end of the capacitor C₄₁ is connected to either the reference voltage source V_{ref} or the ground.

Next, the controller 22 uses the comparator 11 to compare and convert the lower-order bit (MSB-1) of the MSB (S214). At this time, a voltage that appears at the input terminal of the comparator 11 is expressed by Equation 8.

$${V}_{out \_ MSB - 1} ( c ) = \frac{1}{1 + {C}_{adj} / ( 8 C )} ( - {V}_{i n} + \frac{1}{2} {V}_{ref} D [ 3 ] + \frac{1}{4} {V}_{ref} ) \qquad ( 8 )$$

That is, an operation similar to a second cycle of the general SAR-AD conversion is realized.

When the conversion of the lower-order bit of the MSB is completed, the controller 22 sends to the capacitance control line PHI_f(2) a control signal of “1” to control the switches SW22 and SW24 to disconnect the one ends of the capacitors C₄₂ and C₃₂ from the open end (S216). With this, the total capacitance of the capacitance DACs is completely restored.

Next, as shown in FIG. 12D, the controller 22 controls the switches SW23 and SW24 via the AND gate sections IC12 and IC22 to connect the one ends of the capacitors C₃₁ and C₃₂ to either the reference voltage source V_{ref} or the ground and controls the switch SW25 to connect the one end of the capacitor C₂ to the reference voltage source V_{ref}. Further, the controller 22 controls the switch SW22 via the AND gate section IC21 to connect the one end of the capacitor C₄₂ to the same connection destination as the capacitor C₄₁ (S218). Here, in the figure, “D[2]V_{ref}” represents a product of the output of the comparator 11 and the reference voltage source V_{ref}, which is obtained during the MSB-1 conversion period. Thus, the one ends of the capacitors C₃₁ and C₃₂ are connected to either the reference voltage source V_{ref} or the ground.

When the predetermined capacitors are connected to the reference voltage source, the controller 22 uses the comparator 11 to compare and convert the MSB-2 (S220).

After that, by similarly executing switching of capacitor connection (S222), connection of the capacitors to the reference voltage source (S224), and comparison and conversion of the LSB (S226), the controller 22 can obtain AD conversion results for all the four bits.

It should be noted that although in the example shown in FIGS. 10 and 12, the division ratio of the capacitance is set as 1/2, it is not limited thereto. As long as the ratio between the capacitance (constituent capacitance of the capacitance DACs) to be converted and the other capacitance (capacitance of the capacitor having the same capacitance as the capacitor for LSB processing) satisfies the relationship of being a power of 2, the ratio of 1/4, 1/6, 1/8, or the like may be set.

As mentioned above, in the AD converter according to this embodiment, during the MSB conversion period and the MSB-1 conversion period, the total capacitance of the capacitance DACs is reduced, and thus it is possible to suppress the influence of the excessive input signal without providing the adjusting capacitor C_{adj}. Further, in the AD converter according to this embodiment, SAR-AD conversion is realized without dividing at least the capacitor associated with LSB processing, and thus it is possible to effectively suppress the influence of the excessive input signal even if there is limitation on the design process of the circuit.

### Configuration of Third Embodiment

Next, an AD converter according to a third embodiment will be described in detail. The AD converter according to the third embodiment is obtained by allowing, in the AD converter according to the first embodiment, only the capacitance of the capacitor section for MSB processing, which constitutes the capacitance DACs, to be reduced. In the following description, the same elements as in the first and second embodiments will be denoted by the same reference symbols and the duplicated description will be omitted.

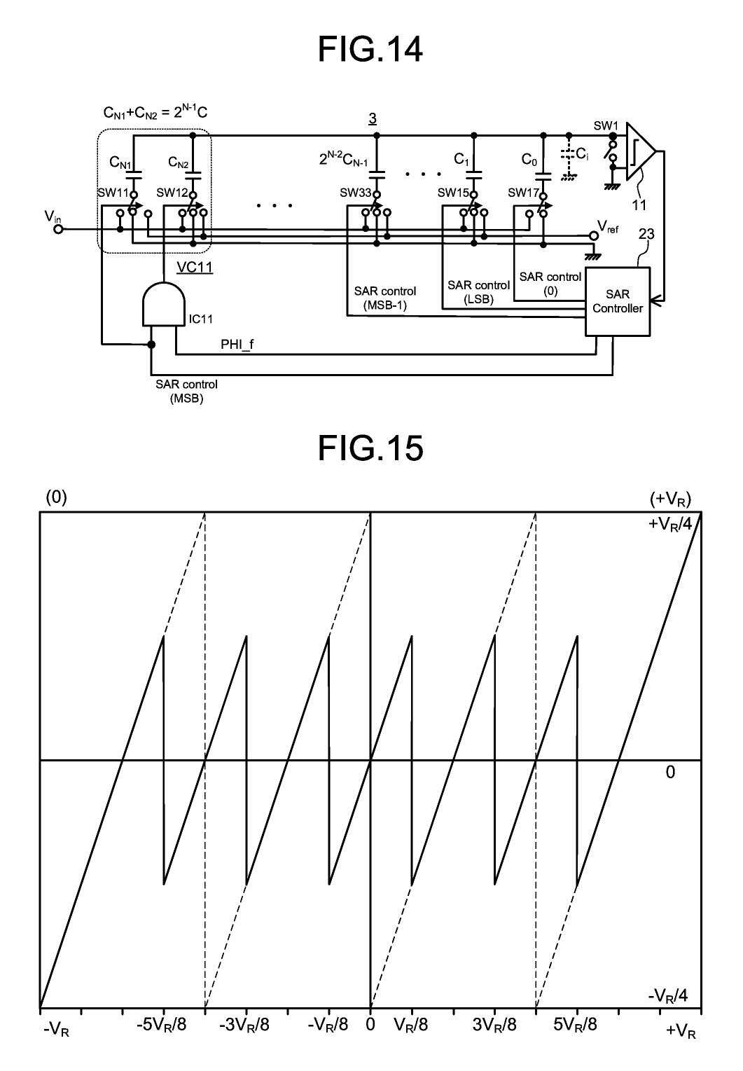

As shown in FIG. 14, the AD converter 3 according to this embodiment includes a variable capacitor section VC11 that serves to process the MSB, capacitors C_{N-1} to C₁ that serve to process bits following the MSB-1, and a capacitor C₀ having the same capacitance value as the capacitor C₁ having the smallest capacitance. The variable capacitor section VC11 and the capacitors C_{N-1} to C₁ each have a capacitance value weighted by a power of 2.

The variable capacitor section VC11 includes capacitors C_{N1} and C_{N2} having the same capacitance value and is capable of disconnecting the capacitor C_{N2} by the AND gate section IC11. A controller 23 has the same function as the controller 21 according to the first embodiment and sends to successive approximation control lines and a capacitance control line control signals.

The controller 23 is capable of controlling, as in the second embodiment, the total capacitance of the variable capacitor section VC11 and realizing SAR-AD conversion by switching connection destinations of one ends of the variable capacitor section VC11 and the capacitors C_{N-1} to C₀ to any of an input terminal Vᵢₙ, a reference voltage source V_{ref}, a ground, and an open end. Further, by reducing the total capacitance of the variable capacitor section VC11 at least during an MSB-processing period, it is possible to suppress the influence of the excessive input signal without providing the adjusting capacitor C_{adj}. In addition, as in the second embodiment, by limiting the capacitance to be divided to that of the capacitor section for MSB processing, it is possible not only to provide degree of freedom in attenuation adjustment of the internal amplitude but also to alleviate the restriction of minimum capacitance.

### Configuration of Fourth Embodiment

Next, an AD converter according to a fourth embodiment will be described in detail. The AD converter according to the fourth embodiment is obtained by changing, in the AD converter according to the first embodiment, the configuration of the variable capacitor section VC11. In the following description, the same elements as in the first embodiment will be denoted by the same reference symbols and the duplicated description will be omitted.

In the AD converters according to the first to third embodiments, by bringing some capacitors constituting the capacitance DACs into floating state, the voltage amplitude (internal amplitude) of an input signal to be input into the comparator is reduced. Here, when the capacitors of the capacitance DACs are held in floating state, there is a fear that one ends of the capacitors held in floating state becomes sources of noise contamination due to substrate noise coupling via a parasitic capacitance or power-source noise coupling via a capacitance that parasitizes a switch, for example. Noise generated via the capacitors of the capacitance DACs results in a determination error or miss judgment (miss code) of the comparator. In view of this, in the AD converter according to the fourth embodiment, as an AD conversion algorithm during a period when the signal amplitude control is being performed (e.g., MSB-processing period), a redundancy algorithm is applied.

FIG. 15 shows voltage characteristics showing an input voltage of the AD converter and an output voltage to the comparator in a certain (kth) AD conversion cycle, in which the horizontal axis denotes an input signal voltage and the vertical axis denotes an output voltage to an input node of the comparator. In the figure, the solid lines represent voltage characteristics to which the redundancy algorithm used in the AD converter according to this embodiment is applied. Further, in the figure, the broken lines represent voltage characteristics to which a non-redundancy algorithm is applied.

As shown by the broken lines of FIG. 15, in the SAR-AD converter to which the non-redundancy algorithm is applied, a change in the input voltage of from 0 to V_{R} in a kth AD conversion cycle is output as a voltage change to the comparator that ranges from −V_{R}/4 to V_{R}/4. That is, it can be seen that a voltage value at the input node of the comparator becomes 1/4 of the input signal voltage in the case of the circuit configuration shown in FIG. 15. That is because the conversion algorithm is based on two bits. In a general algorithm based on 1 bit, an input signal range in a k+1th AD conversion cycle becomes half of the input range of the kth AD conversion cycle.

Further, in FIG. 15, the range in the horizontal axis represents an input range in which kth AD conversion can be performed without miss codes and the range in the vertical axis represents an input range in which k+1th AD conversion can be performed without miss codes. If a judgment voltage value in the kth AD conversion is changed due to noise and an output of the comparator to an input node departs from the range of from −V_{R}/4 to V_{R}/4, it departs from the input range of the k+1th AD conversion, which results in a miss code.

On the other hand, as shown by the solid lines of FIG. 15, in the SAR-AD converter using the redundancy algorithm, two judgment points are set as determination points (comparing points with a threshold value) of an input signal by the comparator. That is, by setting two comparing points (in FIG. 15, 3V_{R}/8 and 5V_{R}/8) between the input signal voltage of the comparator and the threshold value with respect to 1 bit, it is possible to provide a margin of the judgment voltage because the peak of the output voltage to the comparator lowers. With this, even if some error in the judgment voltage occurs, it is possible to realize accurate AD conversion.

In the case of the redundancy algorithm, the plurality of judgment points are provided unlike the non-redundancy algorithm while these judgment voltages can be set only by controlling a capacitance, and thus it is not necessary to provide a plurality of comparators. Further, although in the example shown in FIG. 15, 0.5-bit redundancy is added to 1-bit judgment, the degree of adding redundancy may be extended, for example, 0.5 bit for 2 bits.

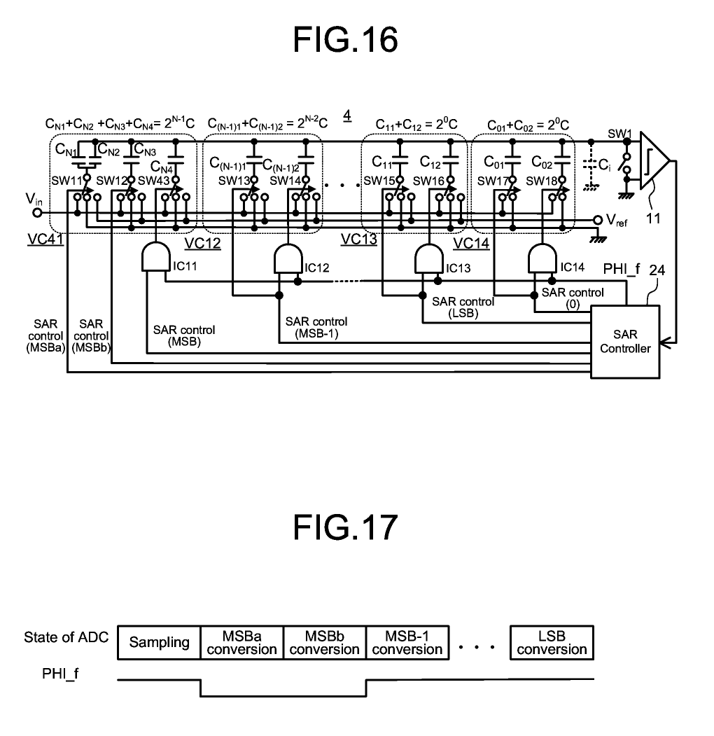

Hereinafter, a configuration of the fourth embodiment will be described. As shown in FIG. 16, the AD converter 4 according to this embodiment is obtained by replacing the variable capacitor section VC11 of the AD converter 1 shown in FIG. 1 by a variable capacitor section VC41. The variable capacitor section VC41 includes capacitors C_{N1}, C_{N2}, C_{N3}, and C_{N4} and switches SW11, SW12, and SW43. The capacitors C_{N1} to C_{N4} are connected to each other at one terminals (common terminals) thereof. To the other terminals of the capacitors C_{N1} to C_{N4}, connected are common terminals of the switches SW11, SW12, and SW43. The switches SW11, SW12, and SW43 function to connect, under control by an external device, the other terminals of the capacitors C_{N1} to C_{N4} to any one of an input terminal Vᵢₙ, a reference voltage source V_{ref}, a ground, and an open end, the other terminals being connected to the common terminals thereof.

A controller 24 is an arithmetic unit that executes operations for a successive approximation and corresponds to the controller 21 shown in FIG. 1. The controller 24 sends, according to an output of the comparator 11, control signals to successive approximation control lines (SAR_control) connected to the variable capacitor section VC41 and to a capacitance control line (PHI_f) that controls the total capacitance of the variable capacitor sections VC41 and VC12 to VC14 (sum of capacitance values of the capacitors).

The successive approximation control lines are connected to the switches SW11 to SW18. Thus, via the control signals sent to the successive approximation control lines, the controller 24 is capable of controlling the common terminals of the switches SW11 to SW18 to be connected to any of the input terminal Vᵢₙ, the reference voltage source V_{ref}, and the ground.

The AND gate sections IC11 to IC14 function to turn on/off connection of at least one of the capacitors included in the variable capacitor sections VC41 and VC12 to VC14. As shown in FIG. 16, to one input terminals of the AND gate sections IC11 to IC14, connected are the successive approximation control lines, and to the other input terminals, connected is the capacitance control line. Output terminals of the AND gate sections IC11 to IC14 are respectively connected to the switches SW43 and SW14 to SW18 connected to the one capacitors (C_{N3} and C_{(N-1)2} to C₀₂) of the variable capacitor sections VC41 and VC12 to VC14 so as to act to connect and disconnect the common terminals and open terminals of the switches SW43 and SW14 to SW18. Thus, via the control signal sent to the capacitance control line, the controller 24 is capable of controlling the total capacitance of the variable capacitor sections VC41 and VC12 to VC14 to be reduced.

FIG. 17 shows a relationship between the operation of this AD converter 4 and the control signal sent to the capacitance control line. As shown in FIG. 17, in the AD converter 4 according to this embodiment, the two judgment points for MSB processing are set and MSB conversion is performed in two steps (MSBa and MSBb). While the AD converter 4 is converting the MSB, that is, while the AD converter 4 is processing the MSBa and the MSBb, the controller 24 sets the control signal sent to the capacitance control line (PHI-f) to “0”. Specifically, during a period when the control signal sent to the capacitance control line is “0”, out of the group of the capacitors in the variable capacitor sections VC41 and VC12 to VC14, the capacitors C_{N3} to C₀₂ are disconnected and only the capacitors C_{N2} and C_{N2} to C₀₁ are connected. It should be noted that the ratio of the total capacitance between the variable capacitor sections VC41 and VC12 to VC13 is not changed before and after the total capacitance is reduced by half.

### Specific Example and Operation of Fourth Embodiment

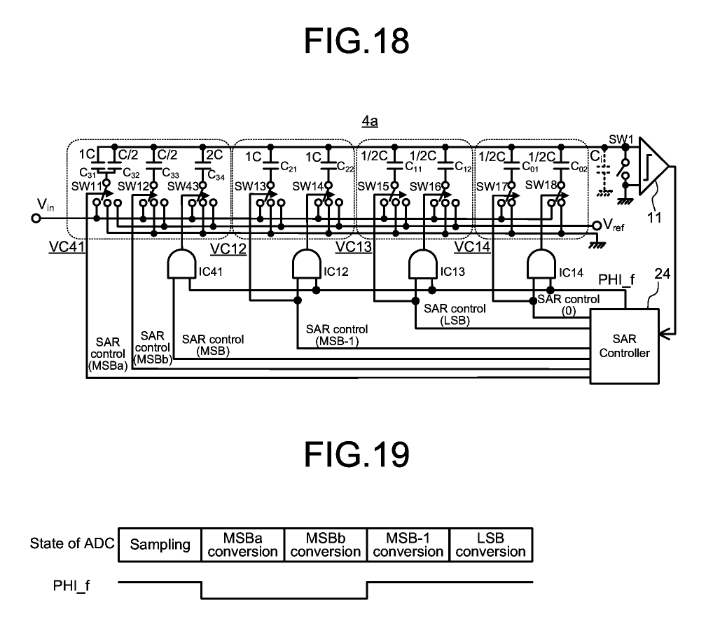

Next, referring to FIG. 18, a specific example and an operation of the AD converter according to the fourth embodiment will be described. FIG. 18 shows an AD converter 4a that converts an input signal into a 3-bit signal, the AD converter 4a being obtained by setting the resolution N to 3 in the AD converter 4 shown in FIG. 17.

As shown in FIG. 18, the AD converter 4a according to this example includes variable capacitor sections VC41 and VC12 to VC14. Assuming that the unit capacitance is represented by C, the variable capacitor sections VC41 and VC12 to VC14 each have a capacitance so that the ratio of 4C (=1C+1C/2+1C/2+2C), 2C (=1C+1C), 1C (=1C/2+1C/2), and 1C can be satisfied.

In the AD converter 4 (AD converter 4a) according to the fourth embodiment, the total capacitance of the capacitance DACs is reduced during the period of the MSB conversion cycle in the AD conversion cycle. Specifically, the controller 24 sends, during an MSBa-processing period and an MSBb-processing period, to the capacitance control line a control signal of “0” to reduce the total capacitance of the capacitance DACs (FIG. 19).

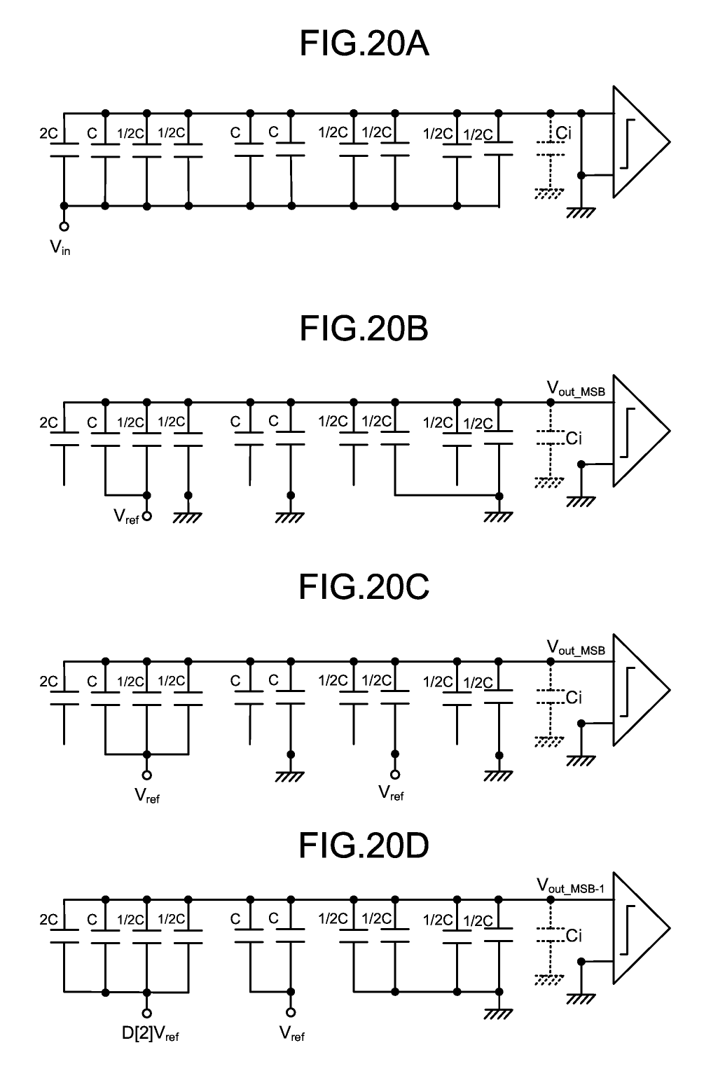

Next, referring to FIGS. 20A to 20D, the operation of the AD converter according to the fourth embodiment will be described. FIGS. 20A to 20D show operation states of the AD converter 4a using equivalent circuits. The SAR-AD conversion of the AD converter according to this embodiment includes five phases of sampling (FIG. 20A), MSBa and MSBb conversion (FIGS. 20B and 20C), MSB-1 conversion (FIG. 20D), and LSB conversion (not shown) and the amplitude attenuation control is performed only during an MSBa conversion period and an MSBb conversion period as shown in FIG. 19.

Hereinafter, operations for MSBa processing and MSBb processing, which are different from those of the AD converter according to the first embodiment, will be described.

During the MSBa-processing period, the controller 24 divides the capacitors of the variable capacitor section VC41 into four capacitors 2C, 1C, 1C/2, and 1C/2. Then, the controller 24 brings the capacitor 2C into floating state, connects one of the capacitors 1C/2 to the ground, and connects the capacitor 1C and the other of the capacitors 1C/2 to the reference voltage source V_{ref} (FIG. 20B). Regarding the variable capacitor sections VC12 to VC14, the controller 24 brings, as in the first embodiment, one capacitors of the paired capacitors into floating state and connects the other capacitors to the ground. A voltage Vₒᵤₜ_{_{—}}_{MSB} that appears at the input terminal of the comparator 11 during this period is expressed by Equation 9.

$${V}_{out \_ MSB} ( b - 1 ) = \frac{1}{1 + {C}_{adj} / ( 4 C )} ( - {V}_{i n} + \frac{3}{8} {V}_{ref} ) \qquad ( 9 )$$

On the other hand, during the MSBb-processing period, regarding the variable capacitor section VC41, the controller 24 brings the capacitor 2C into floating state and connects the other capacitors to the reference voltage source V_{ref}. Further, in the variable capacitor section VC13, the one of the capacitors 1C/2, which is not held in floating state, is disconnected from the ground and connected to the reference voltage source V_{ref} (FIG. 20C). A voltage Vₒᵤₜ_{_{—}}_{MSB} that appears at the input terminal of the comparator 11 during this period is expressed by Equation 10.

$${V}_{out \_ MSB} ( b - 2 ) = \frac{1}{1 + {C}_{adj} / ( 4 C )} ( - {V}_{i n} + \frac{5}{8} {V}_{ref} ) \qquad ( 10 )$$

As mentioned above, it can be seen that also in the case where AD conversion is performed on the MSB in accordance with the redundancy algorithm, the input voltage of the comparator can be reduced.

It should be noted that although in this example, the MSB is provided with 0.5-bit redundancy, it can be also applied to the case of 2 bits+0.5 bit or 4 bits+0.5 bit by similarly extending the MSB. That is, it is possible to extend the value to not only 1 bit, but also N bit(s).

In this embodiment, only by controlling the capacitors of the capacitance DACs, a plurality of judgment voltages of the comparator are generated, and thus it is possible to realize the redundancy algorithm without providing a plurality of comparators.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An analog-to-digital (AD) converter, comprising:
a plurality of weighted capacitors, the weighted capacitors being connected to each other at one ends thereof, each of the weighted capacitors having a capacitance value weighted at a predetermined ratio, the weighted capacitors including at least one variable capacitance capacitor capable of reducing the capacitance value;
a comparator including an input coupled to the one ends of the plurality of weighted capacitors;
a plurality of switches configured to connect the other ends different from the one ends of the plurality of weighted capacitors to any one of an input terminal into which an input signal is input, a reference voltage source used for successive approximation of the input signal, a ground, and an open terminal;
a successive approximation controller configured to control the plurality of switches to sample the input signal onto the plurality of weighted capacitors, and generate a comparative voltage for successive approximation of the input signal by using the reference voltage source, to thereby execute a successive approximation; and
a capacitance controller configured to control the plurality of switches to reduce a capacitance value of the variable capacitance capacitor.

2. The AD converter according to claim 1,
wherein out of the plurality of weighted capacitors, a weighted capacitor used for calculation of a most significant bit (MSB) is formed by the variable capacitance capacitor.

3. The AD converter according to claim 1,
wherein each of the plurality of weighted capacitors has a capacitance value weighted at the ratio of a power of 2.

4. The AD converter according to claim 1,
wherein the variable capacitance capacitor includes a plurality of capacitors connected to each other at one ends thereof; and
wherein the capacitance controller controls the plurality of switches to increase and reduce the number of connection of the plurality of capacitors.

5. The AD converter according to claim 1, further comprising
a reference capacitor having one end connected to the one ends of the plurality of weighted capacitors, the reference capacitor having the same capacitance value as a capacitor having the smallest capacitance value among the plurality of weighted capacitors,
wherein a sum of capacitance values of the plurality of weighted capacitors and the reference capacitor is 2^{N}C where a resolution of AD conversion is represented by N and a unit capacitance value is represented by C.

6. The AD converter according to claim 1,
wherein the plurality of weighted capacitors are formed by a variable capacitance capacitor capable of reducing the capacitance value.

7. The AD converter according to claim 1,
wherein a capacitor having the smallest capacitance value among the plurality of weighted capacitors has a fixed capacitance value.

8. The AD converter according to claim 4,
wherein a capacitor having the smallest capacitance value among the plurality of weighted capacitors and the reference capacitor each have a fixed capacitance value.

9. The AD converter according to claim 2,
wherein the weighted capacitor used for calculation of the MSB comprises three or more capacitors including a redundancy calculation capacitor.

10. An information processing apparatus, comprising the AD converter according to claim 1.
